(19) United States
(12) Patent Application Publication
(10) Pub. No.: US 2023/0188009 A1
(43) Pub. Date: Jun. 15, 2023

(54) SENSOR SYSTEM AND METHOD FOR OPERATING A SENSOR SYSTEM

(71) Applicant: MICRO-EPSILON MESSTECHNIK GMBH & CO. KG, Ortenburg (DE)

(72) Inventors: Michael KURAN, Furstenzell (DE); Norbert REINDL, Furstenzell (DE); Thomas HASLINGER, Ortenburg (DE); Thomas WISSPEINTNER, Ortenburg (DE); Guenter SCHALLMOSER, Ruhstorf (DE)

(21) Appl. No.: 17/793,543

(22) PCT Filed: Jun. 22, 2021
(86) PCT No.: PCT/DE2021/200084

§ 371 Date: Jul. 18, 2022

(30) Foreign Application Priority Data
Sep. 2, 2020 (DE) 102020211083.2

(51) Int. Cl. H02K 11/20; G01R 33/09; G01B 7/30

(52) U.S. Cl. CPC H02K 11/20; G01R 33/093; G01R 33/096; G01B 7/30

(57) ABSTRACT

A sensor system having a distance sensor (1) for detecting the distance between two objects (3,4) that can be moved relative to one another and having a magnetic field sensor (2) for detecting a magnetic field between the objects (3,4), in particular for detecting a gap width and a magnetic field between a rotor and a stator, and having a selection device (13), wherein a measurement signal from the distance sensor (1) or a measurement signal from the magnetic field sensor (2) can be supplied for further processing via the selection device (13). Furthermore, a method for operating a sensor system is described.

### CROSS-REFERENCE TO RELATED APPLICATIONS

This application is a national stage entry application under 35 U.S.C. 371 of PCT Patent Application No. PCT/DE2021/200084, filed on 22 Jun. 2021, which claims priority to German Patent Application No. 10 2020 211 083.2, filed on 2 Sep. 2020, the entire contents of each of which are incorporated herein by reference.

### FIELD

The disclosure relates to a sensor system having a distance sensor for detecting the distance between two objects that are movable relative to one another and having a magnetic field sensor for detecting a magnetic field between the objects.

Furthermore, the disclosure relates to a method for operating a sensor system.

### BACKGROUND

The air gap between the rotor and stator in electric motors is important for the functionality and service life of the motor. On the one hand, the gap should be as small as possible so that the efficiency of the motor is as high as possible. A large air gap reduces the magnetic force between the rotor and stator. On the other hand, the gap must not be too small in order to keep the rotor and stator from coming into contact with each other, especially during changing operating states. In general, this applies both to rotating electric motors and to linear motors with the air gap between the rotor and the stator.

The gap must first be set correctly during assembly. Furthermore, it is desirable to also monitor the gap during operation. The gap can change due to wear, for example of the bearings, or due to changing loads during operation. The gap should therefore be monitored so that there is no contact when the motor is running and thus no major damage.

In addition to a purely geometric gap measurement, i.e. a measurement of the distance between the rotor and stator, it is often desirable, for the operation of electric motors, to detect the magnetic field in the gap. For example, the state of the windings or even the efficiency of the motor can be determined from the magnetic field.

There are already measuring systems in the prior art that measure the gap dimension, on the one hand, and the magnetic field or the magnetic flux in the gap, on the other. EP 1 870 987 discloses a clearance gap measurement assembly consisting of a clearance gap dimension measurement device and a clearance gap magnetic flux measurement device, which obtains a clearance gap dimension input signal and a clearance gap magnetic flux input signal simultaneously from similar locations in a manner synchronized with respect to time and position.

In EP 1 870 987, the measurement signals for distance and magnetic flux are processed simultaneously, i.e. at the same time. The voltage signals used for this must therefore be processed at the same time so that the downstream processor can process them. It is not disclosed how the processing takes place. However, this requires at least two AD converters that can process analog signals at the same time. This is complex and associated with costs.

In order to detect two analog signals simultaneously with sufficiently high resolution, two AD converters are required, which detect the measurement signals for the gap and the magnetic field simultaneously, i.e. at the same time. This requires two fast, high-resolution AD converters. These converters must also be synchronized exactly, which places high demands on the timing and thus on the computer (microcontroller, computer, etc.).

### SUMMARY

The present disclosure is therefore based on the object of designing and refining a sensor system in such a way that a distance and a magnetic field can be reliably detected with simply designed means and thus inexpensively. Furthermore, a method for operating a sensor system is to be specified, in which reliable operation is made possible with simple means and thus inexpensively.

According to the disclosure, the aforementioned object is achieved in reference to the sensor system by means of the features of claim 1. Thus, a sensor system is specified having a distance sensor for detecting the distance between two objects that can be moved relative to one another and having a magnetic field sensor for detecting a magnetic field between the objects, in particular for detecting a gap width and a magnetic field between a rotor and a stator, and having a selection device, wherein a measurement signal from the distance sensor or a measurement signal from the magnetic field sensor can be supplied for further processing via the selection device.

With regard to the method, the underlying object is achieved by means of the features of claim 12. Thus, a method for operating a sensor system is specified, preferably according to any of claims 1 to 11, having a distance sensor for detecting the distance between two objects that can be moved relative to one another and having a magnetic field sensor for detecting a magnetic field between the objects, in particular for measuring a gap width and a magnetic field between a rotor and a stator, and having a selection device, wherein a measurement signal from the distance sensor or a measurement signal from the magnetic field sensor can be supplied for further processing via the selection device.

In a manner according to the disclosure, it has been recognized that, contrary to a prejudice among experts, simultaneous detecting or processing of two measurement signals, i.e. at the same time, is not necessary. It is a significant simplification if the two measurement signals are detected or processed one after the other directly. Therefore, synchronization is not required, which means that the structure with regard to the required components is considerably simplified, so that costs are saved. The sensor system serves in particular to monitor the gap width between a stator and a rotor, i.e. the distance between the stator and the rotor, and the magnetic field in the gap.

Reference is made to the fact that several distance sensors and magnetic field sensors can also be provided, wherein they can preferably be arranged in pairs, for example on a common substrate. If the sensor system is used to monitor the gap between a rotor and a stator, pairs of distance sensors and magnetic sensors, for example, can be distributed around the rotor or stator in the circumferential direction.

The distance sensor can be a capacitive distance sensor or an inductive distance sensor or an optical distance sensor or an eddy-current sensor. In the simplest case, the capacitive distance sensor has a measuring electrode, the shape of which can be adapted to the geometric requirements. A capacitive sensor has the advantage that it is easy to implement, wherein the other aforementioned inductive distance sensors, optical distance sensors, or eddy-current sensors can also be used and provide reliable measured values.

According to a further embodiment, the magnetic field sensor can be a flux sensor or a Hall-effect sensor or a magnetoresistive sensor (MR sensor), in particular an anisotropic magnetoresistive sensor (AMR sensor), or a giant magnetoresistive sensor (GMR sensor). A flux sensor detects the magnetic flux between objects. In a further manner, the magnetic field sensor can have a conductor loop or several conductor loops that form a coil, in which a voltage U_{ind} is induced based on the flux change according to the law of induction U_{ind}=dΦ/dt. Such a design is easy and inexpensive to implement.

In another manner, the selection device can have a multiplexer. By arranging a multiplexer, a measurement signal from the distance sensor or one from the magnetic field sensor can be supplied for further processing in a simple manner, for example in an alternating manner in each case.

According to an embodiment, a preamplifier can be arranged between the selection device and the distance sensor and/or a preamplifier can be arranged between the selection device and the magnetic field sensor. Alternatively or additionally, it is conceivable for an analog/digital converter and/or a computer to be arranged. In one manner, only a single analog/digital converter is arranged, which is possible due to the selection device, since the measurement signals from the distance sensor and the magnetic field sensor can be supplied to the analog/digital converter one after the other. If several distance sensors and magnetic field sensors are arranged, they can be combined in pairs, and a single analog/digital converter and possibly a single multiplexer can be provided for each such pair.

In a further manner, at least one temperature sensor for detecting the temperature can be arranged in the region between the movable objects, for example a gap between the rotor and the stator. The temperature also allows conclusions to be drawn about the operating state of the device, for example an electric motor. An excessively high temperature can negatively affect the electrical properties of the motor or cause damage. The operational safety of the motor and thus of the entire system can be increased by means of integrated state monitoring. Separate temperature sensors could be dispensed with due to the combination of the distance sensor and the magnetic field sensor. There are different means of temperature measurement:

a) Applying a temperature sensor (e.g. a thermocouple or a PT100) on or in the substrate;

b) Providing a conductor loop on or in the substrate, wherein this is supplied with direct current and the temperature is inferred from the change in the ohmic resistance;

c) Using an existing conductor loop or coil of the magnetic field sensor would be advantageous, wherein this is supplied with direct current and the ohmic resistance is measured.

These temperature signals could also be provided to the AD converter with the multiplexer.

Alternatively or additionally, the distance sensor and the magnetic field sensor and possibly the temperature sensor and/or the selection device and/or an analog/digital converter and/or a computer can be arranged on a common substrate or in a common housing. The substrate can be a printed circuit board or a ceramic substrate, for example. For example, the distance sensor is surrounded by the coil. Due to the concentric arrangement, the two measured variables are detected at the same point. However, the distance sensor and magnetic field sensor could also be arranged next to one another. A very practical solution is to arrange the sensors one behind the other on a substrate. By integrating the two measurements into one housing or on one substrate, significant cost advantages can be achieved, since, for example, the mechanical connection to/assembly with the mechanical system only has to take place once. This makes it easier to align the sensors to one another both during installation and subsequent maintenance.

Furthermore, it is conceivable that the substrate is designed in one layer, which represents an simple design. The distance sensor and the magnetic field sensor can then be arranged in one plane. In one manner, the substrate can be multi-layered, for example a multi-layer printed circuit board or a multi-layer ceramic, in particular using LTCC technology. An arrangement on different levels of the substrate would thus also be possible, wherein the distance sensor and the magnetic field sensor can be arranged offset from one another or also one behind the other. Due to the multi-layer arrangement, the coil can also be multi-layered. In this way, sufficiently high inductance can be achieved without expanding the surface area of the coil too much.

According to an embodiment, a position sensor can be arranged to determine the position of the first component relative to the second component. For example, an angle of rotation between a stator and a rotor can be detected in this way. If the positioning of the position sensor relative to the distance sensor and the magnetic field sensor is known, changes in individual poles in the rotor or stator can be detected by detecting the angle of rotation. Such significant changes are, in particular, changes in the magnetic field of individual poles, which may indicate a winding short in the case of electromagnetic poles. An assignment of the error to the respective pole is of particular advantage here. In the case of linear motors, the position and thus the relative position between the rotor and stator would be detected in a completely analog manner.

In the method according to the disclosure, the position of the first component relative to the second component can be determined via a position sensor. Furthermore, it is conceivable that, taking into account the position detected by the position sensor, a spatial assignment of the detected distance and/or the detected magnetic field takes place. Therefore, it is not necessary to detect distance signals and magnetic field strength signals at the same time. The detection of a currently applicable angle of rotation or a relative position as relates to a distance or magnetic field strength value makes this requirement unnecessary. Distance sensors and magnetic field strength sensors can thus be evaluated separately in terms of time and space. The signals could be further combined in another computer unit, in particular they could also be offset against one another.

In a further manner, the distance values and the magnetic field strength values can be evaluated separately from one another in terms of time and/or space. Alternatively or additionally, the distance values and the magnetic field strength values can be offset against one another in such a way that a distance dependency of the magnetic field strength detection is compensated.

There are then various possibilities for advantageously designing and refining the teaching of the present disclosure. For this purpose, reference is made, on the one hand, to the claims subordinate to claims 1 and 12 and, on the other hand, to the following explanation of exemplary embodiments of the disclosure with reference to the drawing. In connection with the explanation of the exemplary embodiments of the disclosure with reference to drawings, embodiments and refinements of the teachings are also explained in general.

### BRIEF DESCRIPTION OF THE SEVERAL VIEWS OF THE DRAWINGS

FIG. 1 a schematic diagram of an exemplary embodiment of a sensor system according to the disclosure;

FIG. 2 a schematic diagram of the arrangement of a sensor system according to the disclosure on the components to be monitored;

FIG. 3 a further schematic diagram of the arrangement of the sensor system according to the disclosure on the components to be monitored;

FIG. 4 a schematic diagram of an exemplary embodiment of a distance sensor and a magnetic field sensor of a sensor system according to the disclosure;

FIG. 5 a schematic diagram of an exemplary embodiment of the electronics of a sensor system according to the disclosure, which are required for processing the measurement signals;

FIG. 6 a schematic diagram of a further exemplary embodiment of the electronics of a sensor system according to the disclosure, which are required for processing the measurement signals;

FIG. 7 a schematic diagram of an exemplary embodiment of the electronics of a sensor system according to the disclosure, which are required for processing the measurement signals; and

FIG. 8 a schematic diagram of an exemplary embodiment of the electronics of a sensor system according to the disclosure, which are required for processing the measurement signals.

### DETAILED DESCRIPTION OF THE DISCLOSURE

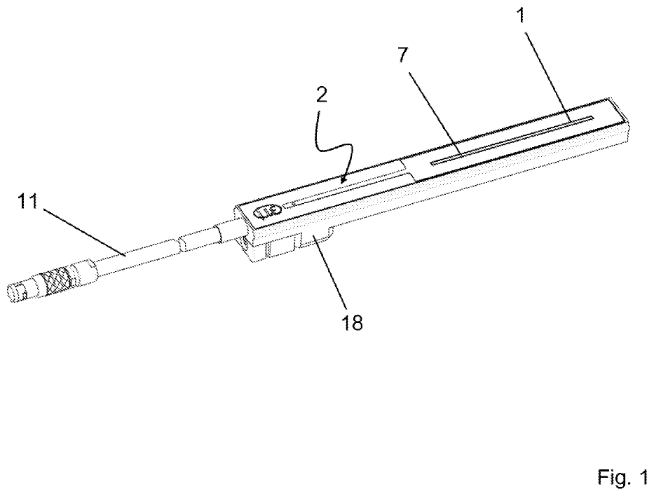

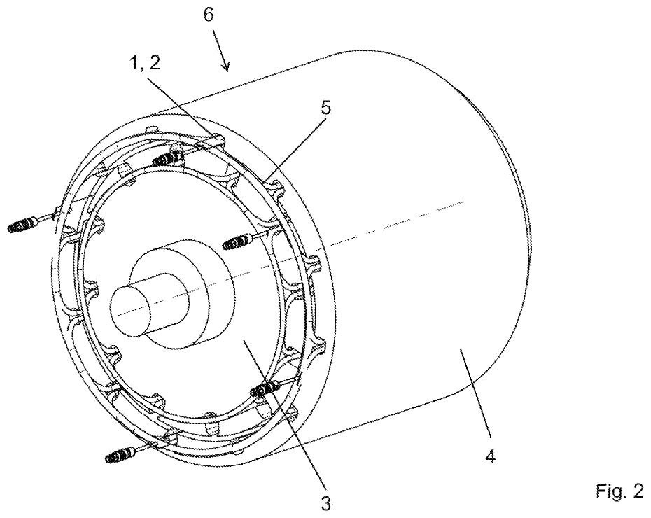

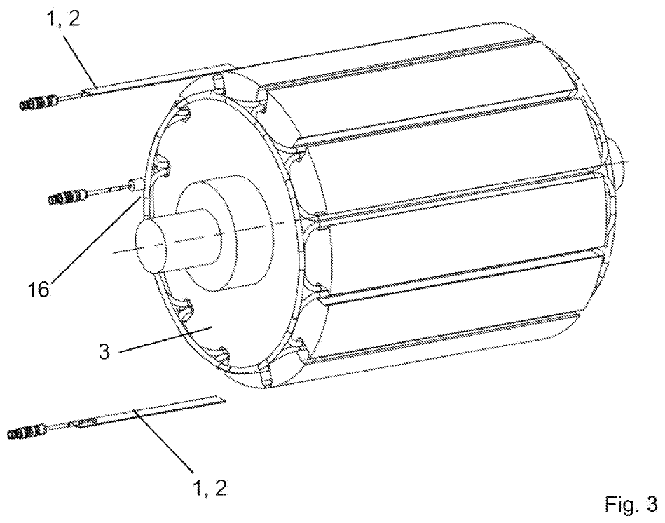

In addition to the sensor system according to the disclosure, the method according to the disclosure is also explained with reference to the figures. FIG. 1 shows a sensor system for detecting geometric and magnetic variables, namely a distance sensor 1 and a magnetic field sensor 2, which are arranged in a common housing 18. The distance sensor 1, for example a capacitive distance sensor 1, measures the distance between the first object 3 and the second object 4 in the gap 5. The first object 3 is a rotor and the second object 4 is a stator of an electric motor 6 (cf. FIG. 2). In addition to an electric motor, this can be any other arrangement that has a rotor and a stator or even a linear drive. FIGS. 2, 3 clearly show that several pairs of distance sensor 1 and magnetic field sensor 2 are arranged about the rotor 3 or the stator 4.

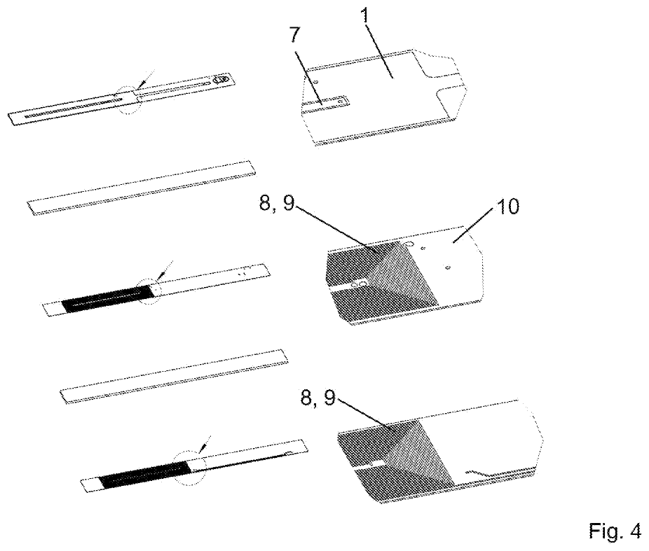

FIG. 4 shows the structure of an exemplary sensor system. In the simplest case, the capacitive distance sensor 1 is implemented by a measuring electrode 7, the shape of which can be adapted to the geometric requirements. Instead of a capacitive distance sensor 1, other types of distance sensors, for example inductive, optical, or eddy-current sensors, could also be used. Furthermore, the measuring electrode 7 is shown in FIG. 4.

In the simplest case, the magnetic field sensor 2 is a flux sensor that detects the magnetic flux in the gap 5. It consists of at least one conductor loop 8 forming a coil 9. The coil 9 lies in the plane of the substrate 10 and, with a corresponding arrangement of the substrate 10 in the gap 5, almost perpendicular to the magnetic field lines.

The distance sensor 1 and the magnetic field sensor 2 are arranged in or on a common substrate 10. This can be a printed circuit board or a ceramic substrate, for example. For example, the capacitive distance sensor 1 is surrounded by the coil 9. Due to the concentric arrangement, the two measured variables are detected at the same point. However, the distance sensor 1 and magnetic field sensor 2 could also be arranged next to one another. As a very practical solution, the sensors can also be installed one behind the other on a common element.

By combining the distance sensor 1 and magnetic field sensor 2 in a common housing or on a common substrate 10, a common line 11 can be arranged.

In the simplest design, the substrate 10 has a single layer. The distance sensor 1 and the magnetic field sensor 2 are then arranged in a common plane. In one manner, the substrate 10 is multi-layered, i.e. a multi-layer printed circuit board or a multi-layer ceramic, in particular using LTCC technology. An arrangement on different levels of the substrate 10 would thus also be possible, wherein the distance sensor 1 and the magnetic field sensor 2 can be arranged offset from one another or also one behind the other. Due to the multi-layer arrangement, the coil 9 can also have a multi-layer design, as shown in FIG. 3. In this way, sufficiently high inductance can be achieved without expanding the surface area of the coil 9 too much.

FIG. 3 also shows that a position sensor 16 is arranged, which is used to determine an angle of rotation between the first object 3 (stator) and the second object 4 (rotor).

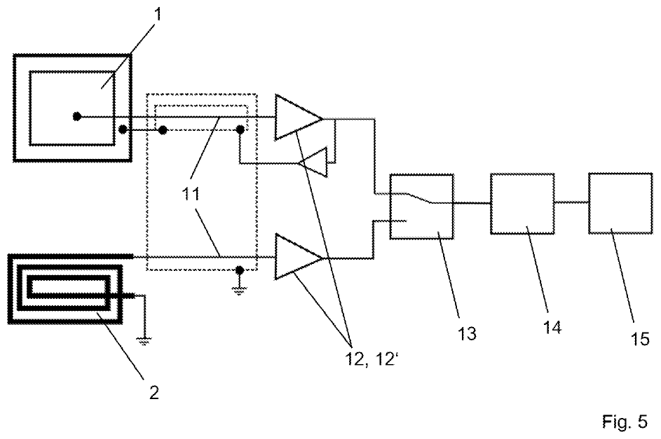

The electronics required for processing the measurement signals are shown in FIGS. 5 to 8. Accordingly, the electronics can likewise be arranged on the substrate 10. In the simplest case, the electronics only consist of signal pre-processing. This could be, for example, (analog) preamplifiers 12, 12′, which amplify the two signals so that they can be transmitted to the downstream electronics at a higher signal level. Filtering of the signals, for example using low-pass, high-pass, or band-pass filters, is also possible.

Digital processing of the signals as early as possible is advantageous. For this purpose, the electronics contain a selection device 13, preferably a multiplexer 13, and an analog/digital converter 14. The multiplexer 13, for example, has at least two inputs and one output. The distance signal is present at one input and the magnetic field signal at the second input. Initially, only the first input is switched through, so that the first signal (e.g. distance) is present at the analog/digital converter 14 and can be digitized. The second input is then switched through, so that the second signal (e.g. magnetic flux) is present at the analog/digital converter 14 and can be digitized. The two signals are then processed in a computer 15, for example a microcontroller.

The multiplexer 13 can be designed either as a separate component or as a component integrated into an analog/digital converter 14; both solutions can be implemented using standard components. The computer 15 can also be arranged on the substrate 10. Filtering can also be done digitally in the computer 15. Thus, the signals can be fully evaluated on the substrate 10.

It is also possible to place parts of the signal processing up to complete signal processing away from the substrate 10 in separate evaluation electronics. Only the most necessary components such as the distance sensor 1 and the magnetic field sensor 2 would then be contained on the substrate 10.

The two measurement signals can then be transmitted to the downstream evaluation electronics either via separate lines or via a common line 11. If an analog/digital converter 13 is used, the signals are then transmitted to the downstream electronics via a digital interface. The advantage of the digital interface is that it is immune to interference from the electromagnetic environment in the electric motor.

The evaluation of the signals can be carried out in the computer 15 by placing them in different relationships to one another depending on the requirements.

This includes mechanical variables such as air gap (min, max) across all individual poles or the eccentricity, conicity, and ovality of the rotor or stator and, for example, shaft displacement of the rotor due to bearing wear.

The magnetic field of individual poles can be measured as an essential electrical variable, which can even be compensated for in terms of distance by calculating the respective distance signals.

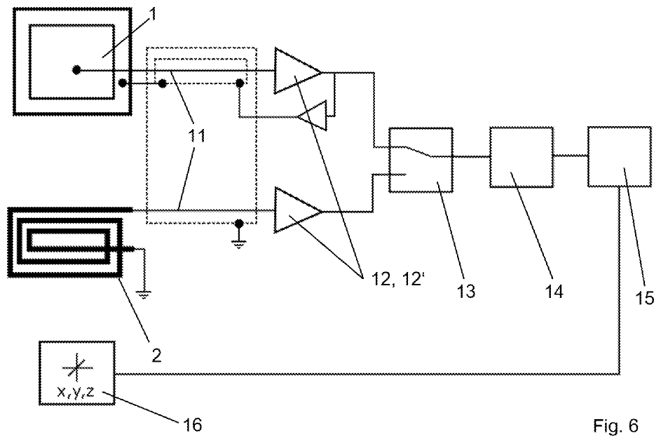

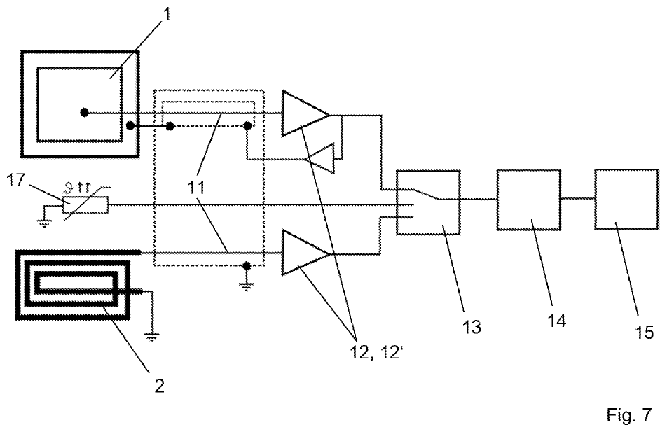

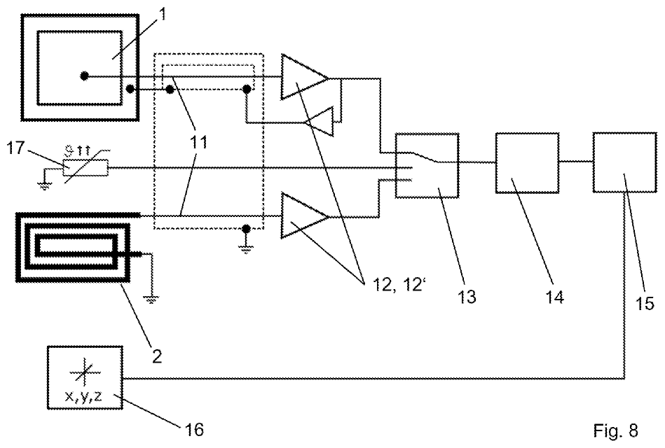

The exemplary embodiment shown in FIG. 7 corresponds to the exemplary embodiment from FIG. 5, wherein a temperature sensor 17 is also arranged. Furthermore, the exemplary embodiment according to FIG. 8 corresponds to the exemplary embodiment from FIG. 6, wherein a temperature sensor 17 is also arranged.

To avoid repetition with regard to further embodiments of the device according to the disclosure and the method according to the disclosure, reference is made to the general part of the description and to the appended claims.

Finally, it should be expressly noted that the above-described exemplary embodiments of the device according to the disclosure and of the method according to the disclosure are used solely to explain the claimed teaching, but do not restrict it to the exemplary embodiments.

### LIST OF REFERENCE NUMERALS

1 Distance sensor
2 Magnetic field sensor
3 First object
4 Second object
5 Gap
6 Electric motor
7 Measuring electrode
8 Conductor loop
9 Coil
10 Substrate
11 Line
12 Preamplifier
13 Selection device
14 Analog/digital converter
15 Computer
16 Position sensor
17 Temperature sensor
18 Housing

1. A sensor system comprising:
a distance sensor (1) for detecting the distance between two objects (3,4) that can be moved relative to one another,
a magnetic field sensor (2) for detecting a magnetic field between the objects (3,4) and
a selection device (13), wherein, a measurement signal from the distance sensor (1) or a measurement signal from the magnetic field sensor (2) can be supplied for further processing via the selection device (13).

2. The sensor system according to claim 1, wherein the distance sensor (1) is a capacitive distance sensor or an inductive distance sensor or an optical distance sensor or an eddy-current sensor.

3. The sensor system according to claim 1, wherein the magnetic field sensor (2) is a flux sensor or a Hall-effect sensor or a magnetoresistive sensor (MR sensor

4. The sensor system according to claim 1, wherein the magnetic field sensor (2) has one or more conductor loops (8).

5. The sensor system according to claim 1, wherein the selection device (13) has a multiplexer (13).

6. The sensor system according claim 1, further comprising at least one of:
a preamplifier (12) i& arranged between the selection device (13) and the distance sensor (1), and
a preamplifier (12′) is arranged between the selection device (13) and the magnetic field sensor (2).

7. The sensor system according claim 1, further comprising at least one of:
an analog/digital converter (14),
preferably only a single analog/digital converter (14), and
a computer (15).

8. The sensor system according to claim 1, further comprising at least one temperature sensor (17) for detecting the temperature in the region between the moveable objects (3,4).

9. The sensor system according to claim 1, wherein the distance sensor (1) and the magnetic field sensor (2) are arranged on a common substrate (10) with at least one of:
the temperature sensor (17),
the selection device (13),
an analog/digital converter (14), and
a computer (15).

10. The sensor system according to claim 1 wherein the distance sensor (1) and the magnetic field sensor (2) are arranged next to one another on a common substrate (10) or distance sensor (1) and the magnetic field sensor (2) are arranged one behind the other or one above the other in or on different layers of a multilayer substrate (10).

11. The sensor system according to claim 1, wherein a position sensor (16) is arranged to determine the position of the first component (3) relative to the second component (4).

12. A method for operating a sensor system, comprising:
having a distance sensor (1) for detecting the distance between two objects (3,4) that can be moved relative to one another using a distance sensor (1),
detecting a magnetic field between the objects (3,4) using a magnetic field sensor (2), and
wherein, a measurement signal from the distance sensor (1) or a measurement signal from the magnetic field sensor (2) is supplied for further processing via a selection device (13).

13. The method according to claim 12, wherein the position of the first component (3) relative to the second component (4) is determined via a position sensor (16).

14. The method according to claim 13, wherein a spatial assignment of the detected distance and/or the detected magnetic field takes place taking into account the position detected by the position sensor (16).

15. The method according to claim 12, wherein the distance values and the magnetic field strength values are evaluated separately from one another in terms of time and/or space.

16. The method according to claim 12, wherein the distance values and the magnetic field strength values are offset against one another in such a way that a distance dependency of the magnetic field strength detection is compensated.

17. The sensor system according to claim 1, wherein the magnetic field sensor (2) detects a gap width and a magnetic field between a rotor and a stator.

18. The sensor system according to claim 3 wherein the magnetic field sensor (2) is a one of:
an anisotropic magnetoresistive sensor (AMR sensor); and
a giant magnetoresistive (GMR) sensor.

19. The sensor system according to claim 11, wherein the position sensor (16) is arranged to determine one of:
an angle of rotation between a stator and a rotor; and
a relative position between a rotor and a stator.

20. The method according to claim 12, wherein detecting a magnetic field between the objects (3,4) comprises measuring a gap width and a magnetic field between a rotor and a stator.
